(19) United States
(12) Patent Application Publication
(10) Pub. No.: US 2025/0241148 A1
(43) Pub. Date: Jul. 24, 2025

(54) DISPLAY DEVICE

(71) Applicant: Samsung Display Co., LTD., Yongin-si (KR)

(72) Inventors: Da Sol JEONG, Yongin-si (KR); Dong Gyun KIM, Yongin-si (KR); Tae Seop KIM, Yongin-si (KR); Eun Ho SONG, Yongin-si (KR); Seung Hwan CHO, Yongin-si (KR)

(73) Assignee: Samsung Display Co., LTD., Yongin-si (KR)

(21) Appl. No.: 18/934,717

(22) Filed: Nov. 1, 2024

(30) Foreign Application Priority Data
Jan. 23, 2024 (KR) 10-2024-0010004

(51) Int. Cl. H10K 59/131; H10K 59/80

(52) U.S. Cl. CPC H10K 59/131; H10K 59/80517

(57) ABSTRACT

A display device includes a display area including a pixel and a non-display area; a pixel circuit layer including a pixel circuit; a first electrode disposed on the pixel circuit layer; an emission structure disposed on the first electrode; a second electrode disposed on the emission structure in the display area; a connection electrode electrically connected to the second electrode in the non-display area; a first metal layer disposed on the pixel circuit layer in the non-display area; and a second metal layer including at least a portion disposed on the first metal layer. The second metal layer electrically contacts the connection electrode.

### CROSS-REFERENCE TO RELATED APPLICATION(S)

This application claims priority to and benefits of Korean patent application No. 10-2024-0010004 under 35 U.S.C. § 119 filed on Jan. 23, 2024 in the Korean Intellectual Property Office, the entire contents of which are incorporated herein by reference.

### BACKGROUND

### 1. Technical Field of

Various embodiments of the disclosure relate to a display device.

### 2. Description of the Related Art

With the development of information technology, the importance of display devices as a medium connecting users and information has been emphasized.

Such a display device may include a display area where pixels areas are disposed to display an image, and a non-display area that is an area except the display area. Furthermore, the display device may include electrodes (for example, cathode electrodes) configured to supply power to the pixels. The electrodes of the display device may be deposited in some areas of the display area and the non-display area of the display device.

During a process of manufacturing the display device, some of the electrodes of the display device may be damaged, and the electrodes may be disconnected, so that power may not be properly supplied to the pixels. It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

An aspect of the disclosure is directed to a display device capable of reducing a risk of damage to electrodes of the display device, and appropriately supplying power to a pixel.

An embodiment of the disclosure may provide a display device, including: a display area including a pixel, and a non-display area; a pixel circuit layer including a pixel circuit; a first electrode disposed on the pixel circuit layer; an emission structure disposed on the first electrode; a second electrode disposed on the emission structure in the display area; a connection electrode electrically connected to the second electrode in the non-display area; a first metal layer disposed on the pixel circuit layer in the non-display area; and a second metal layer including at least a portion disposed on the first metal layer. The second metal layer may electrically contact the connection electrode.

In an embodiment, the second metal layer may electrically contact at least a portion of an upper surface of the first metal layer.

In an embodiment, at least a portion of the connection electrode may be disposed on the second metal layer.

In an embodiment, the first metal layer may include at least one or more of Al, Ag, and Cu. The second metal layer may include at least one or more of indium tin oxide (ITO), indium zinc oxide (IZO), Al, Ag, and Cu.

In an embodiment, the first metal layer may have a thickness in a range of about 500 Å to about 1000 Å. The second metal layer may have a thickness in a range of about 50 Å to about 200 Å.

In an embodiment, the first metal layer and the first electrode may be formed through a same process.

In an embodiment, the display device may further include an insulating layer including at least a portion exposing the first electrode. The insulating layer may include: a first insulating layer disposed in the display area; and a second insulating layer disposed in the non-display area. At least a portion of the insulating layer may extend from the display area to the non-display area.

In an embodiment, the insulating layer may include a lower layer and an upper layer disposed on the lower layer. The lower layer may include: a first lower layer; and a second lower layer disposed on the first lower layer. The upper layer may include: a first upper layer; a second upper layer disposed on the first upper layer; and a third upper layer disposed on the second upper layer.

In an embodiment, each of the first lower layer, the second lower layer, the first upper layer, the second upper layer, and the third upper layer may include one or more of silicon oxide (SiOₓ) and silicon nitride (SiNₓ). Each of the first lower layer, the second lower layer, the first upper layer, the second upper layer, and the third upper layer may have a thickness in a range of about 100 Å to about 600 Å.

In an embodiment, at least a portion of the second insulating layer may cover a side surface of the first metal layer. The second metal layer may cover an end of at least the portion of the second insulating layer.

In an embodiment, at least a portion of the second insulating layer may be disposed between the first metal layer and the second metal layer.

In an embodiment, the pixel circuit layer may include: a contact part passing through at least a portion of the pixel circuit layer; a first conductive layer disposed in the display area; and a second conductive layer disposed in the non-display area. The first metal layer may be electrically connected to the second conductive layer through the contact part. The second metal layer may be electrically connected to the first metal layer.

An embodiment of the disclosure may provide a display device including: a display area including a pixel, and a non-display area; a base layer; a pixel circuit layer disposed on the base layer, the pixel circuit layer including a pixel circuit; a first power line and a second power line electrically connected to the pixel circuit; a first electrode disposed on the pixel circuit layer; an emission structure disposed on the first electrode; a second electrode disposed on the emission structure in the display area; a first metal layer disposed on the pixel circuit layer in the non-display area; a connection electrode electrically connected to the second electrode in the non-display area; and a second metal layer including at least a portion disposed on the first metal layer. The non-display area may include a contact area. The second power line and the connection electrode may be electrically connected in the contact area. The second metal layer may electrically contact the connection electrode.

In an embodiment, the second metal layer may electrically contact at least a portion of the first metal layer. The contact area may include: a first contact area disposed on a first side of the display area; a second contact area disposed on a second side of the display area; a third contact area disposed on a third side of the display area; and a fourth contact area disposed on a fourth side of the display area.

In an embodiment, the first metal layer may include at least one or more of Al, Ag, and Cu. The first metal layer may have a thickness in a range of about 500 Å to about 1000 Å. The second metal layer may include at least one or more of indium tin oxide (ITO), indium zinc oxide (IZO), Al, Ag, and Cu. The second metal layer may have a thickness in a range of about 50 Å to about 200 Å. The contact area may include: a fifth contact area disposed between the first contact area and the second contact area; and a sixth contact area disposed between the third contact area and the fourth contact area.

In an embodiment, at least the portion of the second metal layer may overlap the first metal layer in a plan view. The contact area may enclose at least a portion of the display area.

In an embodiment, at least the portion of the second metal layer may overlap the contact area in a plan view.

In an embodiment, at least a portion of the second metal layer may extend from the contact area to the non-display area except the contact area.

In an embodiment, the non-display area may enclose at least a portion of the display area. The pixel circuit layer may include: a contact part passing through at least a portion of the pixel circuit layer; a first conductive layer disposed in the display area; and a second conductive layer disposed in the non-display area. The first metal layer may be electrically connected to the second conductive layer through the contact part. The second metal layer may be electrically connected to the first metal layer.

An embodiment of the disclosure may provide a display device, including: a display area including a pixel, and a non-display area; a pixel circuit layer including a pixel circuit; a first electrode disposed on the pixel circuit layer; an emission structure disposed on the first electrode; a second electrode disposed on the emission structure in the display area; a connection electrode electrically connected to the second electrode in the non-display area; a first metal layer disposed on the pixel circuit layer in the non-display area; and a second metal layer including at least a portion disposed on the first metal layer. At least the portion of the second metal layer may overlap the first metal layer and the connection electrode, in a plan view.

### BRIEF DESCRIPTION OF THE DRAWINGS

The above and other aspects and features of the disclosure will become more apparent by describing in detail embodiments thereof with reference to the attached drawings, in which:

FIGS. 1, 2, and 3 are schematic plan views illustrating the display device in accordance with an embodiment.

FIGS. 4 and 5 are schematic plan views illustrating embodiments of a pixel illustrated in FIG. 1.

FIG. 6 is a schematic sectional view of the display device taken along line A-A′ of FIG. 1.

FIG. 7 is a schematic sectional view illustrating an enlargement of a lower layer and an upper layer of FIG. 6.

FIG. 8 is a schematic sectional view illustrating an embodiment of an emission structure included in a light emitting element of FIG. 6.

FIG. 9 is a schematic sectional view of the display device taken along line B-B′ of FIG. 1 in accordance with an embodiment.

FIG. 10 is a schematic sectional view of the display device taken along line B-B′ of FIG. 1 in accordance with an embodiment.

FIG. 11 is a schematic block diagram illustrating an electrical connection structure of the light emitting element in accordance with an embodiment.

FIG. 12 is a schematic block diagram of a display system in accordance with an embodiment.

FIG. 13 is a schematic perspective diagram illustrating an application example of the display system of FIG. 12.

### DETAILED DESCRIPTION OF THE EMBODIMENTS

As the disclosure allows for various changes and numerous embodiments, example embodiments will be illustrated in the drawings and described in detail in the written description. However, this is not intended to limit the disclosure to described modes of practice, and it is to be appreciated that all changes, equivalents, and substitutes that do not depart from the spirit and technical scope of the disclosure are encompassed in the disclosure.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

It will be further understood that the terms “comprise”, “include”, “have”, etc. when used in the disclosure, specify the presence of stated features, integers, steps, operations, elements, components, and/or combinations of them but do not preclude the presence or addition of one or more other features, integers, steps, operations, elements, components, and/or combinations thereof.

Furthermore, in case that a first part such as a layer, a film, a region, or a plate is disposed on a second part, the first part may be not only directly on the second part but a third part may intervene between them. In addition, when it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Various embodiments of the disclosure relate to a display device. Hereinafter, a display device in accordance with an embodiment will be described with reference to the attached drawings.

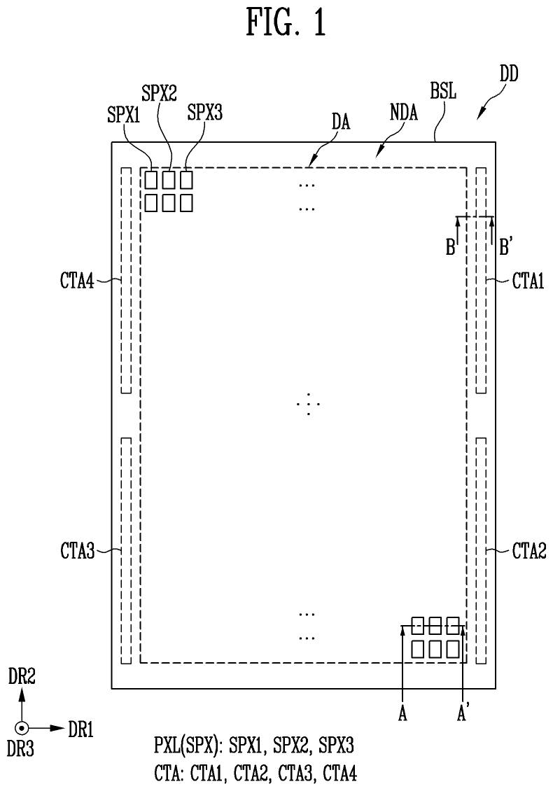

FIGS. 1 to 3 are schematic plan views each illustrating a display device DD in accordance with an embodiment.

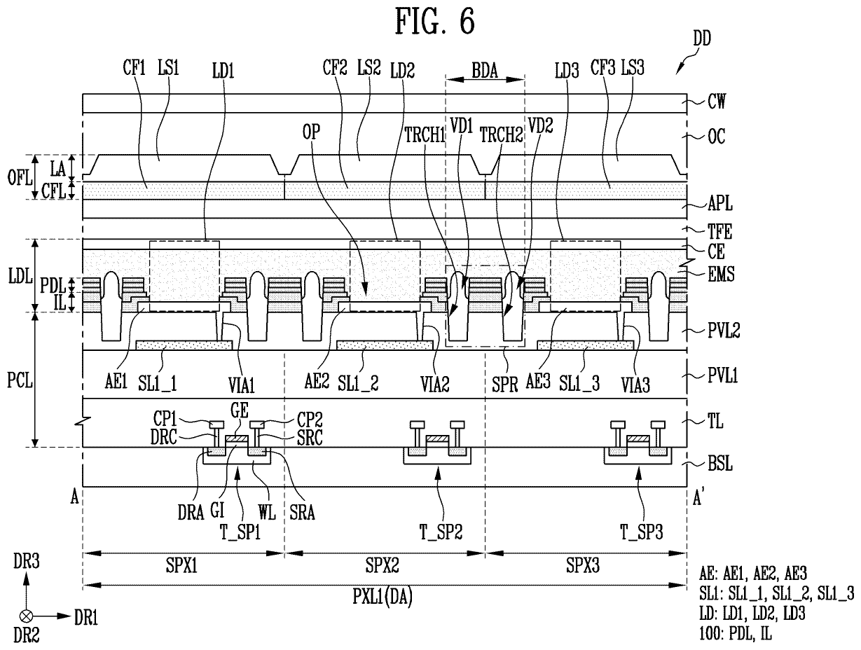

Referring to FIG. 1, the display device DD is configured to emit light. The display device DD may include a light emitting element LD (refer to FIG. 6). In an embodiment, the display device DD may be provided in various shapes. For example, the display device DD may be formed of a rectangular panel having short sides extending in a first direction DR1, and long sides extending a second direction DR2 intersecting with the first direction DR1. In the disclosure, the first direction DR1 may correspond to a row direction of the pixel PXL. The second direction DR2 may be a column direction of the pixel PXL. The third direction DR3 may be a display direction of the display device DD. In an embodiment, the display device DD may be applied to a smart phone, a notebook computer, a table personal computer (PC), a wearable device (for example, a head-mounted device, a smart watch, smart glasses, etc.), a television, or an in-vehicle infotainment system, and the like, and may be applied to various other embodiments.

The display device DD may include a base layer BSL, and pixels PXL disposed on the base layer BSL. The display device DD may further include a driving circuit component (for example, a scan driver and a data driver), lines, and pads which are provided to drive the pixels PXL.

The display device DD may include a display area DA and a non-display area NDA. The non-display area NDA may refer to an area other than (or except) the display area DA. The non-display area NDA may enclose at least a portion of the display area DA.

The base layer BSL may form a base of the display device DD. The base layer BSL may be a rigid or flexible substrate or film. For example, the base layer BSL may be a rigid substrate formed of glass or tempered glass. By way of example, the base layer BSL may include materials having flexible properties, and may be formed of a flexible substrate (or a thin film) made of plastic or metal, or at least one insulating layer. However, the material and/or properties of the base layer BSL are not particularly limited.

In an embodiment, the base layer BSL may be substantially transparent. Here, the words “substantially transparent” may mean that light can pass through the base layer BSL with a transmittance of a given value or more. In an embodiment, the base layer BSL may be translucent or opaque. Furthermore, the base layer BSL may include reflective material depending on the embodiment.

In an embodiment, the base layer BSL may be formed of a silicon substrate. In embodiments, the base layer BSL may include a silicon wafer substrate formed through a semiconductor process. The base layer BSL may include semiconductor material suitable for forming circuit elements. For example, the semiconductor material may include silicon, germanium, and/or silicon-germanium. The base layer BSL may be provided from a bulk wafer, an epitaxial layer, a silicon on insulator (SOI) layer, a semiconductor on insulator (SeOI) layer, or the like within the spirit and the scope of the disclosure. In embodiments, the base layer BSL may include a glass substrate. In embodiments, the base layer BSL may include a polyimide (polyimide) substrate.

The display area DA may refer to an area in which the pixels PXL are disposed. The non-display area NDA may refer to an area in which the pixels PXL are not disposed. The driving circuit component, the lines, and the pads which are connected to the pixels PXL of the display area DA may be disposed in the non-display area NDA.

In an embodiment, the pixels PXL (or sub-pixels SPX) may be arranged (or disposed) according to a stripe or PENTILE™ arrangement structure. However, the disclosure is not limited to the foregoing example.

In accordance with an embodiment, each pixel PXL (or the sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form one pixel PXL which may emit various colors of light. Although FIG. 1 illustrates that each of the pixels PXL may include three sub-pixels SPX1, SPX2, and SPX3, for example, a first sub-pixel SPX1, a second sub-pixel SPX2, and a third sub-pixel SPX3, the disclosure is not limited thereto.

In an embodiment, each of the sub-pixels SPX may have a rectangular, square, or rhombus planar shape. For example, each of the first sub-pixel SPX1, the second sub-pixel SPX2, and the third sub-pixel SPX3 may have a rectangular planar shape having short sides extending in the first direction DR1 and long sides extending in the second direction DR2, as illustrated in FIG. 1. By way of example, each of the sub-pixels SPX may have a square or rhombus planar shape including sides with the same lengths in the first direction DR1 and the second direction DR2.

In an embodiment, the surface areas of the first sub-pixel SPX1, the second sub-pixel SPX2, and the third sub-pixel SPX3 may be substantially the same as each other, but are not limited thereto. For example, at least any one of the surface areas of the first sub-pixel SPX1, the second sub-pixel SPX2, and the third sub-pixel SPX3 may be different from another one. By way of example, any two of the surface area of the first sub-pixel SPX1, the surface area of the second sub-pixel SPX2, and the surface area of the third sub-pixel SPX3 may be substantially the same as each other, and a remaining one may be different from the two. As a further example, the surface area of the first sub-pixel SPX1, the surface area of the second sub-pixel SPX2, and the surface area of the third sub-pixel SPX3 may be different from each other.

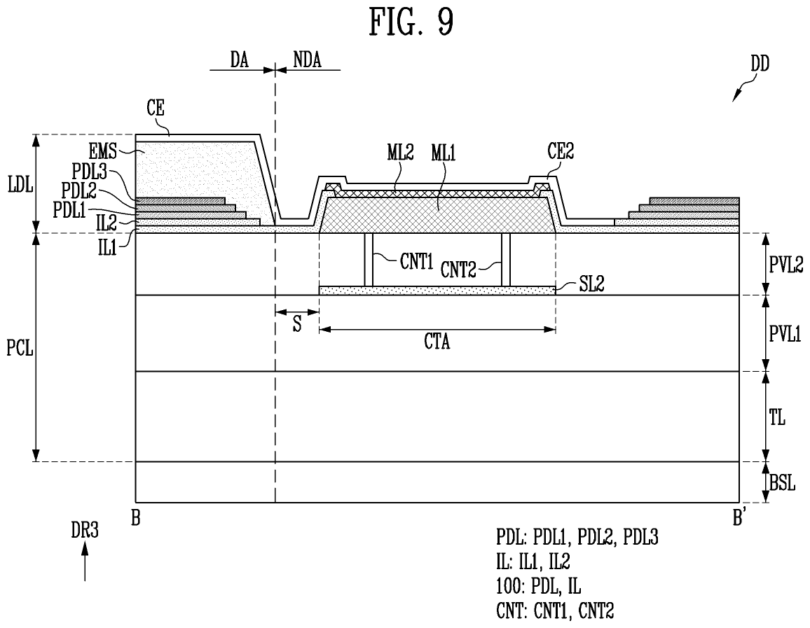

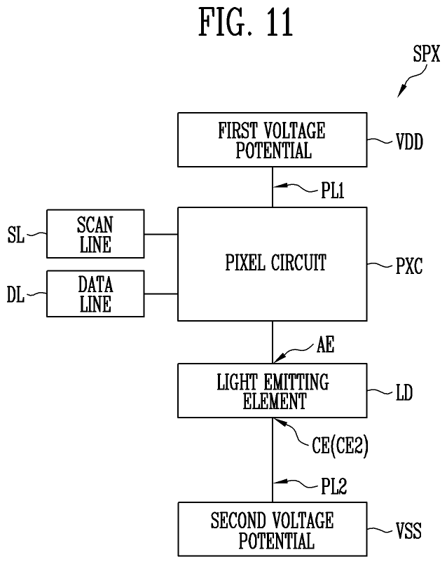

The non-display area NDA may include a contact area CTA. The contact area CTA may be an area where a connection electrode CE2 (refer to FIG. 9) provided to supply power to one electrode (for example, a second electrode CE) of the light emitting element LD is electrically connected to lines {for example, a second power line PL2 (refer to FIG. 11)} that are disposed in the non-display area NDA and connected to the pixels PXL. For example, the contact area CTA may be an area where the connection electrode CE2 (refer to FIG. 9) provided to supply power to one electrode (for example, the second electrode CE) of the light emitting element LD physically contacts the lines {for example, the second power line PL2 (refer to FIG. 11)} that are disposed in the non-display area NDA and connected to the pixels PXL.

The contact area CTA may include areas spaced apart from each other, in a plan view. The number of the contact area CTA is not particularly limited.

In an embodiment (refer to FIG. 1), the contact area CTA may include a first contact area CTA1, a second contact area CTA2, a third contact area CTA3, and a fourth contact area CTA4.

The first contact area CTA1 may be disposed in the non-display area NDA and on a first side (for example, an upper right side) of the display area DA. The second contact area CTA2 may be disposed in the non-display area NDA and on a second side (for example, a lower right side) of the display area DA. The third contact area CTA3 may be disposed in the non-display area NDA and on a third side (for example, a lower left side) of the display area DA. The fourth contact area CTA4 may be disposed in the non-display area NDA and on a fourth side (for example, an upper left side) of the display area DA.

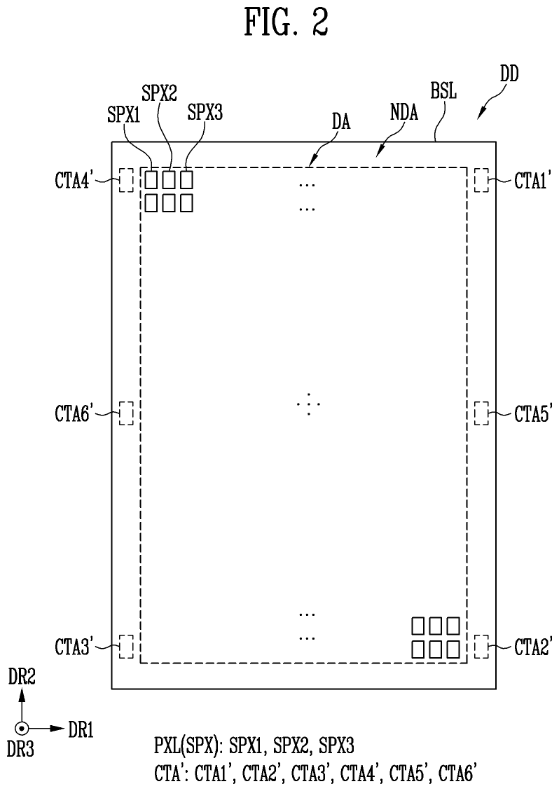

In an embodiment (refer to FIG. 2), a contact area CTA′ may include a first contact area CTA1′, a second contact area CTA2′, a third contact area CTA3′, a fourth contact area CTA4′, a fifth contact area CTA5′, and a sixth contact area CTA6′.

The first contact area CTA1′ may be disposed in the non-display area NDA and on a first side (for example, an upper right side) of the display area DA. The second contact area CTA2′ may be disposed in the non-display area NDA and on a second side (for example, a lower right side) of the display area DA. The third contact area CTA3′ may be disposed in the non-display area NDA and on a third side (for example, a lower left side) of the display area DA. The fourth contact area CTA4′ may be disposed in the non-display area NDA and on a fourth side (for example, an upper left side) of the display area DA. The fifth contact area CTA5′ may be disposed between the first contact area CTA1′ and the second contact area CTA2′. The fifth contact area CTA5′ may be disposed on a fifth side (for example, a right center) of the display area DA. The sixth contact area CTA6′ may be disposed between the third contact area CTA3′ and the fourth contact area CTA4′. The sixth contact area CTA6′ may be disposed on a sixth side (for example, a left center) of the display area DA.

The contact area CTA′ illustrated in FIG. 2 may have a surface area less than the contact area CTA illustrated in FIG. 1. However, the disclosure is not limited to the disclosure, and the surface area of the contact area CTA may be changed.

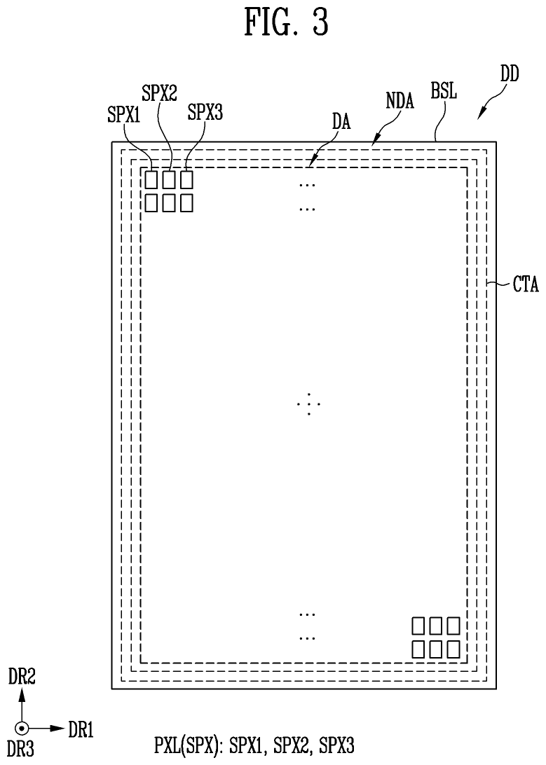

In an embodiment (refer to FIG. 3), the contact area CTA may include a single area. For example, the contact area CTA may be formed of a single area. The contact area CTA may enclose at least a portion of the display area DA. In an embodiment, the contact area CTA may have a shape corresponding to a periphery of the display area DA.

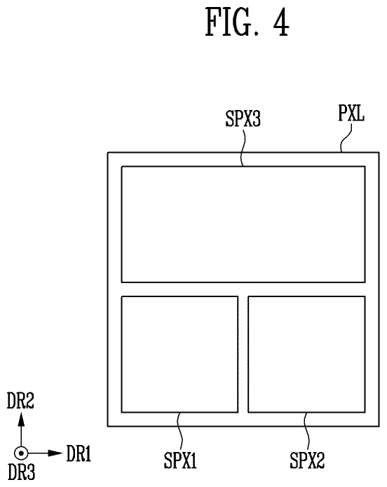

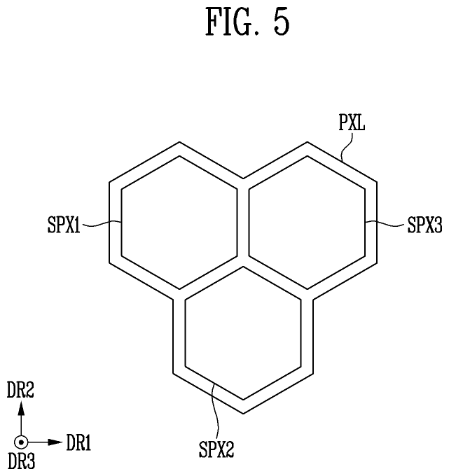

FIGS. 4 and 5 are schematic plan views illustrating embodiments of the pixel PXL illustrated in FIG. 1. Hereinafter, the structure of the pixel PXL in accordance with embodiments will be described with reference to FIGS. 4 and 5.

Referring to FIG. 4, the first sub-pixel SPX1 may be arranged with either the second sub-pixel SPX2 or the third sub-pixel SPX3 in the first direction DR1, and may be arranged with a remaining one in the second direction DR2. For example, the first sub-pixel SPX1 may be arranged with the second sub-pixel SPX2 in the first direction DR1, and the first sub-pixel SPX1 may be arranged with the third sub-pixel SPX3 in the second direction DR2.

In an embodiment, the third sub-pixel SPX3 may be adjacent to the first sub-pixel SPX1 and the second sub-pixel SPX2 in the second direction DR2. In an embodiment, the surface areas of the first and second sub-pixels SPX1 and SPX2 may be substantially the same as each other. The surface area of the third sub-pixel SPX3 may differ from the surface areas of the first and second sub-pixels SPX1 and SPX2. For example, the surface area of the third sub-pixel SPX3 may be greater than the surface area of each of the first and second sub-pixels SPX1 and SPX2.

Referring to FIG. 5, each of the first sub-pixel SPX1, the second sub-pixel SPX2, and the third sub-pixel SPX3 may have a hexagonal (for example, regular hexagonal) planar shape. In an embodiment, two adjacent sides among six sides of each of the first sub-pixel SPX1, the second sub-pixel SPX2, and the third sub-pixel SPX3 may face corresponding sides of other adjacent sub-pixels SPX.

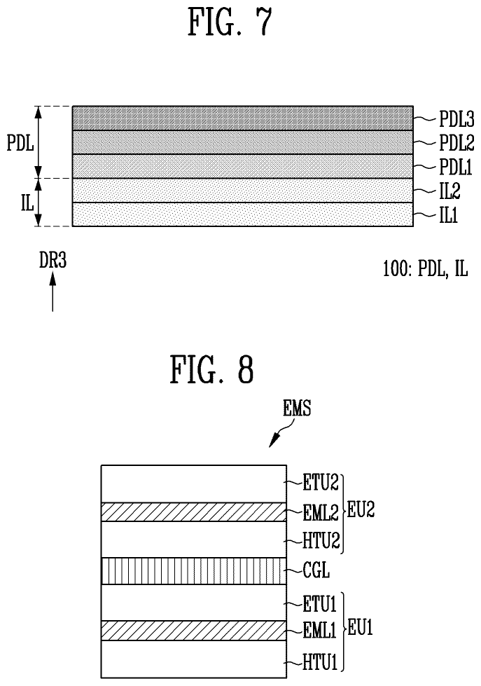

FIG. 6 is a schematic sectional view of the display device DD taken along line A-A′ of FIG. 1. FIG. 6 is a diagram illustrating a sectional view in the display area DA of the display device DD. FIG. 7 is a schematic sectional view illustrating an enlargement of a lower layer and an upper layer of FIG. 6. FIG. 8 is a sectional view illustrating an embodiment of an emission structure included in a light emitting element of FIG. 6. Hereinafter, the display device DD in the display area DA will be described with reference to FIGS. 6 to 8.

Referring to FIG. 6, there may be provided the base layer BSL and a pixel circuit layer PCL disposed on the base layer BSL.

The base layer BSL may be the base of the display device DD described above. The base layer BSL may include a silicon wafer substrate formed through a semiconductor process. For example, the base layer BSL may include silicon, germanium, and/or silicon-germanium. Accordingly, the display device DD may be referred to as an OLED on Silicon (OLEDoS) display device.

The pixel circuit layer PCL may include a transistor layer TL, a first passivation layer PVL1, and a second passivation layer PVL2.

The transistor layer TL may be disposed on the base layer BSL. The base layer BSL and the transistor layer TL may include circuit elements of each of the first sub-pixel SPX1, the second sub-pixel SPX2, and the third sub-pixel SPX3. For example, the base layer BSL and the transistor layer TL may include a transistor T_SP1 of the first sub-pixel SPX1, a transistor T_SP2 of the second sub-pixel SPX2, and a transistor T_SP3 of the third sub-pixel SPX3. The transistor T_SP1 of the first sub-pixel SPX1 may be any one of the transistors included in the sub-pixel circuit of the first sub-pixel SPX1. The transistor T_SP2 of the second sub-pixel SPX2 may be any one of the transistors included in the sub-pixel circuit of the second sub-pixel SPX2. The transistor T_SP3 of the third sub-pixel SPX3 may be any one of the transistors included in the sub-pixel circuit of the third sub-pixel SPX3.

In accordance with an embodiment, in the disclosure, the transistors may include complementary metal-oxide semiconductor (CMOS) circuit elements. In FIG. 6, one of the transistors of each sub-pixel is illustrated for the sake of clear and concise explanation, and the remaining circuit circuits may be omitted.

The transistor T_SP1 of the first sub-pixel SPX1 may include a source area SRA, a drain area DRA, and a gate electrode GE.

The source area SRA and the drain area DRA may be disposed in the base layer BSL. Formed through an ion injection process, a well WL may be disposed in the base layer BSL. The source area SRA and the drain area DRA may be disposed to be spaced apart from each other in the well WL. An area between the source area SRA and the drain area DRA in the well WL may be defined as a channel area.

The gate electrode GE may overlap the channel area between the source area SRA and the drain area DRA, and may be disposed in the transistor layer TL. The gate electrode GE may be spaced apart from the well WL or the channel area by an insulating material such as a gate insulating layer GI. The gate electrode GE may include conductive material.

Layers included in the transistor layer TL may include insulating layers and conductive patterns disposed between the insulating layers. The conductive patterns may include first and second conductive patterns CP1 and CP2. The first conductive pattern CP1 may be electrically connected to the drain area DRA through a drain connector DRC passing through one or more insulating layers. The second conductive pattern CP2 may be electrically connected to the source area SRA through a source connector SRC passing through one or more insulating layers.

Each of the transistor T_SP2 of the second sub-pixel SPX2 and the transistor T_SP3 of the third sub-pixel SPX3 may be configured in the same manner as the transistor T_SP1 of the first sub-pixel SPX1.

As such, the base layer BSL and the transistor layer TL may include circuit elements of each of the first sub-pixel SPX1, the second sub-pixel SPX2, and the third sub-pixel SPX3.

The first passivation layer PVL1 may be disposed on the transistor layer TL. The first passivation layer PVL1 may cover the transistor layer TL and have an overall even surface. The first passivation layer PVL1 may be configured to planarize steps on the transistor layer TL. The first passivation layer PVL1 may include at least one of silicon oxide (SiOₓ), silicon nitride (SiNₓ), and silicon carbon nitride (SiCN), but embodiments are not limited thereto.

On the first passivation layer PVL1, a 1_1-th conductive layer SL1_1, a 1_2-th conductive layer SL1_2, and a 1_3-th conductive layer SL1_3 may be respectively disposed in the first sub-pixel SPX1, the second sub-pixel SPX2, and the third sub-pixel SPX3. Each of the 1_1-th conductive layer SL1_1, the 1_2-th conductive layer SL1_2, and the 1_3-th conductive layer SL1_3 may contact a corresponding circuit element disposed in the transistor layer TL, through a via passing through the first passivation layer PVL1.

In the disclosure, the first conductive layer SL1 may be a conductive layer disposed in the display area DA, and may supply an electrical signal to a first electrode AE of the light emitting element LD.

To planarize steps between the 1_1-th conductive layer SL1_1, the 1_2-th conductive layer SL1_2, and the 1_3-th conductive layer SL1_3, the second passivation layer PVL2 may be disposed on the first passivation layer PVL1, the 1_1-th conductive layer SL1_1, the 1_2- th conductive layer SL1_2, and the 1_3-th conductive layer SL1_3. The second passivation layer PVL2 may cover overall surfaces of the 1_1-th conductive layer SL1_1, the 1_2-th conductive layer SL1_2, the 1_3-th conductive layer SL1_3, and the first passivation layer PVL1, and may have an even surface.

In an embodiment, the second passivation layer PVL2 may be a via layer including a via (for example, a first via VIA1, a second via VIA2, and a third via VIA3) for electrically connecting the light emitting element LD and the first conductive layer SL1, and a contact part CNT (refer to FIG. 9) for electrically connecting a connection electrode CE2 (refer to FIG. 9) and a second conductive layer SL2 (refer to FIG. 9). In an embodiment, the second passivation layer PVL2 may be disposed on an outermost portion (or an uppermost portion) of the pixel circuit layer PCL, thus planarizing a surface of the pixel circuit layer PCL.

A light-emitting-element layer LDL may be disposed on the second passivation layer PVL2. The light-emitting-element layer LDL may include first electrodes AE1 to AE3, a lower layer IL, an upper layer PDL, an emission structure EMS, and a second electrode CE.

The first electrodes AE1 to AE3 may be disposed on the second passivation layer PVL2. The first electrodes AE1 to AE3 may include a 1_1-th electrode AE1, a 1_2-th electrode AE2, and a 1_3-th electrode AE3. On the second passivation layer PVL2, the 1_1-th electrode AE1, the 1_2-th electrode AE2, and the 1_3-th electrode AE3 may be disposed to respectively overlap the 1_1-th conductive layer SL1_1, the 1_2-th conductive layer SL1_2, and the 1_3-th conductive layer SL1_3. The 1_1-th electrode AE1 may be connected to the 1_1-th conductive layer SL1_1 through the first via VIA1 passing through the second passivation layer PVL2. The 1_2-th electrode AE2 may be connected to the 1_2-th conductive layer SL1_2 through the second via VIA2 passing through the second passivation layer PVL2. The 1_3-th electrode AE3 may be connected to the 1_3-th conductive layer SL1_3 through the third via VIA3 passing through the second passivation layer PVL2.

In embodiments, each of the 1_1-th electrode AE1, the 1_2-th electrode AE2, and the 1_3-th electrode AE3 may be an anode electrode of the corresponding light emitting element LD. In embodiments, the 1_1-th electrode AE1, the 1_2-th electrode AE2, and the 1_3-th electrode AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). However, the disclosure is not limited to the aforementioned example. For example, the 1_1-th electrode AE1, the 1_2-th electrode AE2, and the 1_3-th electrode AE3 may include one or more of Al, Ag, and Cu, and may further include one or more of indium tin oxide (ITO), titanium (Ti), titanium nitride (TiN).

In an embodiment, the first electrode AE may have a single-layer structure including one or more of Al, Ag, and Cu. In an embodiment, the first electrode AE may have a triple-layer structure in which a layer including one or more of Al, Ag, and Cu is stacked on a layer including one or more of indium tin oxide (ITO), titanium (Ti), titanium nitride (TiN), and an additional layer including one or more of Al, Ag, and Cu is stacked on the layer including one or more of Al, Ag, and Cu. However, the disclosure is not limited thereto, and the first electrode AE may include metal having a relatively high reflectance.

An insulating layer 100 may be disposed on some portions of the first electrode AE and the second passivation layer PVL2. The insulating layer 100 may include the lower layer IL and the upper layer PDL. The lower layer IL may be disposed under (or below) the upper layer PDL. Hereinafter, in the disclosure, the lower direction is defined as a direction opposite to the third direction DR3, and the upper direction is defined as the third direction DR3.

The lower layer IL and the upper layer PDL may include an opening OP that exposes a portion of the first electrode AE. The lower layer IL and the upper layer PDL may form a pixel defining layer that defines emission areas. The opening OP may define the emission area of each of the first sub-pixel SPX1, the second sub-pixel SPX2, and the third sub-pixel SPX3.

Referring to FIG. 7, in embodiments, the lower layer IL and the upper layer PDL may include inorganic insulating layers. Each of the inorganic insulating layers may include at least one of silicon oxide (SiOₓ) and silicon nitride (SiNₓ). For example, the lower layer IL may include a first lower layer IL1 and a second lower layer IL2 that are sequentially stacked. Each of the first lower layer IL1 and the second lower layer IL2 may include at least one of silicon oxide (SiOₓ) and silicon nitride (SiNₓ).

For example, the upper layer PDL may include a first upper layer PDL1, a second upper layer PDL2, and a third upper layer PDL3 that are sequentially stacked on the lower layer IL. Each of the first upper layer PDL1, the second upper layer PDL2, and the third upper layer PDL3 may include at least one of silicon oxide (SiOₓ) and silicon nitride (SiNₓ). However, the disclosure is not limited to the aforementioned example, and the number of layers that form the lower layer IL and the upper layer PDL may be changed.

In an embodiment, each of the first lower layer IL1, the second lower layer IL2, the first upper layer PDL1, the second upper layer PDL2, and the third upper layer PDL3 may have a thickness in a range of about 100 Å to about 600 Å.

A separator SPR may be provided in a boundary area BDA between adjacent sub-pixels.

The separator SPR may result in creation of discontinuous portions in the emission structure EMS in the boundary area BDA. For example, the emission structure EMS may be interrupted or bent in the boundary area BDA by the separator SPR.

The separator SPR may be provided in or on the upper layer PDL and the lower layer IL. The upper layer PDL and the lower layer IL may include one or more trenches TRCH1 and TRCH2 in the boundary area BDA as the separator SPR. In embodiments, as illustrated in FIG. 6, the one or more trenches TRCH1 and TRCH2 may pass through the upper layer PDL and the lower layer IL and partially pass through the second passivation layer PVL2. However, the disclosure is not limited to the foregoing.

Due to the first trench TRCH1 and the second trench TRCH2, discontinuous portions such as a first void VD1 and a second void VD2 in the boundary area BDA may be formed in the emission structure EMS. Some of the layers stacked in the emission structure EMS may be interrupted (or cut or separate) or bent by the first void VD1 and the second void VD2. For example, at least one charge generation layer included in the emission structure EMS may be interrupted by the first void VD1 and the second void VD2. As such, due to the first and second trenches TRCH1 and TRCH2, portions of the emission structure EMS included in each of the first sub-pixel SPX1, the second sub-pixel SPX2, and the third sub-pixel SPX3 are at least partially separated from each other.

In FIG. 6, there is illustrated the case where the first and second voids VD1 and VD2 are formed in the emission structure EMS in the boundary area BDA, but this case is for illustrative, and embodiments are limited thereto. For example, a valley having a concave shape may be formed in the emission structure EMS in the boundary area BDA. Depending on the shapes of the first and second trenches TRCH1 and TRCH2, the discontinuous portions formed in the emission structure EMS may be changed in various ways.

In embodiments, the emission structure EMS may be formed through a process such as vacuum deposition, or inkjet printing. The same materials as the emission structure EMS may be positioned on bottom surfaces adjacent to the first passivation layer PVL1 in the first and second trenches TRCH1 and TRCH2.

The emission structure EMS may be disposed on the first electrode AE exposed through the opening OP. The emission structure EMS may be charged into the opening OP, and may be disposed over the entireties of the first sub-pixel SPX1, the second sub-pixel SPX2, and the third sub-pixel SPX3.

The emission structure EMS may be at least partially interrupted or bent in the boundary area BDA by the separator SPR. Consequently, during the operation of the display device DD, current leaking from each of the first sub-pixel SPX1, the second sub-pixel SPX2, and the third sub-pixel SPX3 to the adjacent sub-pixel through the layers included in the emission structure EMS may be reduced. Consequently, the light emitting elements LD may be operated with relatively high reliability.

Referring to FIG. 8, in an embodiment, the emission structure EMS may have a tandem structure in which a first emission structure EU1 and a second emission structure EU2 are stacked. The emission structure EMS may have a substantially identical configuration in each of the first to third light emitting elements LD1 to LD3 of FIG. 6.

Each of the first emission structure EU1 and the second emission structure EU2 may include a light generation layer configured to generate light in response to current applied thereto. The first emission structure EU1 may include a first emission layer EML1, a first electron transport component ETU1, and a first hole transport component HTU1. The first emission layer EML1 may be disposed between the first electron transport component ETU1 and the first hole transport component HTU1. The second emission structure EU2 may include a second emission layer EML2, a second electron transport component ETU2, and a second hole transport component HTU2. The second emission layer EML2 may be disposed between the second electron transport component ETU2 and the second hole transport component HTU2.

Each of the first and second hole transport components HTU1 and HTU2 may include at least one of a hole injection layer and a hole transport layer, and may further include a hole buffer layer, an electron blocking layer, and the like, as needed. The first and second hole transport components HTU1 and HTU2 may have the same configuration or have different configurations.

Each of the first and second electron transport components ETU1 and ETU2 may include at least one of an electron injection layer and an electron transport layer, and may further include an electron buffer layer, a hole blocking layer, and the like, as needed. The first and second electron transport components ETU1 and ETU2 may have the same configuration or have different configurations.

A connection layer, which can be provided in the form of a charge generation layer CGL, may be disposed between the first emission structure EU1 and the second emission structure EU2 to connect the first and second emission structures EU1 and EU2 to each other. In embodiments, the charge generation layer CGL may have a stacked structure including a p-dopant layer and an n-dopant layer. For example, the p-dopant layer may include a p-type dopant such as HAT-CN, TCNQ, or NDP-9, and the n-dopant layer may include alkali metal, alkaline earth metal, lanthanide metal, or a combination thereof. However, embodiments are not limited to the aforementioned example.

In embodiments, the first emission layer EML1 and the second emission layer EML2 may generate light in different colors. The light emitted from the first emission layer EML1 and the second emission layer EML2 may be mixed to be visible as white light. For instance, the first emission layer EML1 may generate light in blue, and the second emission layer EML2 may generate light in yellow. In embodiments, the second emission layer EML2 may include a stacked structure including a first sub-light generation layer configured to generate light in red, and a second sub-light generation layer configured to generate light in green. Light in red and light in green may be mixed to provide light in yellow. An intermediate layer configured to perform functions of transporting holes and/or blocking the transport of electrons may be further disposed between the first and second sub-light generation layers.

In other embodiments, the first emission layer EML1 and the second emission layer EML2 may generate light in the same color.

Although there has been an embodiment where the emission structure EMS has a tandem in which the first emission structure EU1 and the second emission structure EU2 are stacked, the disclosure is not limited thereto.

In an embodiment, each of the first to third light emitting elements LD1 to LD3 may include one emission structure. Here, the respective emission structures included in the first to third light emitting elements LD1 to LD3 may be configured to emit light in different colors. For example, the emission structure of the first light emitting element LD1 may emit light in red, the emission structure of the second light emitting element LD2 may emit light in green, and the emission structure of the third light emitting element LD3 may emit light in blue. Unlike in FIG. 6, portions of the emission structure EMS corresponding to the first sub-pixel SPX1, the second sub-pixel SPX2, and the third sub-pixel SPX3 may be separated from each other, and each of the portions of the emission structure EMS may be disposed in the corresponding opening OP of the upper layer PDL. At least some of the color filters CF1 to CF3 may be omitted.

The second electrode CE may be disposed on the emission structure EMS. The second electrode CE may be a cathode electrode of the light emitting element LD. The second electrode CE may be provided in common to the first sub-pixel SPX1, the second sub-pixel SPX2, and the third sub-pixel SPX3. The second electrode CE may function as a half mirror, partially transmitting and partially reflecting light emitted from the emission structure EMS.

The 1_1-th electrode AE1, the portion of the emission structure EMS that overlaps the 1_1-th electrode AE1, the portion of the second electrode CE that overlaps the 1_1-th electrode AE1 may form the first light emitting element LD1. The 1_2-th electrode AE2, the portion of the emission structure EMS that overlaps the 1_2-th electrode AE2, the portion of the second electrode CE that overlaps the 1_2-th electrode AE2 may form the second light emitting element LD2. The 1_3-th electrode AE3, the portion of the emission structure EMS that overlaps the 1_3-th electrode AE3, and the portion of the second electrode CE that overlaps the 1_3-th electrode AE3 may form the third light emitting element LD3.

A thin-film encapsulation layer TFE may be disposed on the second electrode CE. The thin-film encapsulation layer TFE may prevent oxygen and/or water or the like from penetrating into the light-emitting-element layer LDL.

The optical functional layer OFL may be disposed on the thin-film encapsulation layer TFE. In embodiments, the optical functional layer OFL may be attached to the thin-film encapsulation layer TFE through an adhesive layer APL. For example, the optical functional layer OFL may be fabricated through a separate process and attached to the thin-film encapsulation layer TFE by the adhesive layer APL. The adhesive layer APL may further perform a function of protecting underlying layers including the thin-film encapsulation layer TFE.

The optical functional layer OFL may include a color filter layer CFL and a lens array LA. The color filter layer CFL may include first to third color filters CF1 to CF3 respectively corresponding to the first sub-pixel SPX1, the second sub-pixel SPX2, and the third sub-pixel SPX3. The first to third color filters CF1 to CF3 may transmit light in different wavelength ranges. For example, the first to third color filters CF1 to CF3 may respectively transmit red light, green light, and blue light.

In embodiments, the first to third color filters CF1 to CF3 may partially overlap each other in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 respectively corresponding to the first sub-pixel SPX1, the second sub-pixel SPX2, and the third sub-pixel SPX3. The first to third lenses LS1 to LS3 may respectively direct light emitted from the first to third light emitting elements LD1 to LD3 in intended paths, thus enhancing the light output efficiency.

An overcoat layer OC may be disposed on the lens array LA. The overcoat layer OC may cover the optical functional layer OFL, the thin film encapsulation layer TFE, the light emission structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

A cover window CW may be disposed on the overcoat layer OC. The cover window CW is configured to protect layers thereunder. The cover window CW may have a refractive index higher than a refractive index of the overcoat layer OC. The cover window CW may include glass, but embodiments are not limited thereto. For example, the cover window CW may be an encapsulation glass configured to protect components disposed thereunder. In other embodiments, the cover window CW may be omitted.

FIG. 9 is a schematic sectional view of the display device taken along line B-B′ of FIG. 1. FIG. 9 is a diagram illustrating a sectional view in the display area DA and the non-display area NDA of the display device DD. In FIG. 9, for the sake of clear and concise explanation, there are illustrated only the base layer BSL, the pixel circuit layer PCL, and the light-emitting-element layer LDL.

Hereinafter, components disposed in the non-display area NDA of the display device DD in accordance with an embodiment will be described with reference to FIG. 9.

Referring to FIG. 9, the display device DD may include a connection electrode CE2 disposed in the non-display area NDA. The connection electrode CE2 may be connected (for example, electrically connected) to the second electrode CE disposed in the display area DA. The connection electrode CE2 may be formed through the same process as the second electrode CE disposed in the display area DA. For example, the second electrode CE may be deposited through a same process as the connection electrode CE2, and may include a same material as the connection electrode CE2.

The light-emitting-element layer LDL may further include a first metal layer ML1 and a second metal layer ML2. The first metal layer ML1 may be disposed on the pixel circuit layer PCL (or the second passivation layer PVL2). The first metal layer ML1 may contact the pixel circuit layer PCL (or the second passivation layer PVL2).

The first metal layer ML1 may be formed through a same process as the first electrode AE disposed in the display area DA. For example, the first metal layer ML1 may be deposited through the same process as the first electrode AE, and may include a same material as the first electrode AE. For example, the first metal layer ML1 may include one or more Al, Ag, and Cu, and may include one or more of indium tin oxide (ITO), titanium (Ti), titanium nitride (TiN).

In an embodiment, the first metal layer ML1 may have a single-layer structure including one or more of Al, Ag, and Cu. In an embodiment, the first metal layer ML1 may have a triple-layer structure in which a layer including one or more of Al, Ag, and Cu is stacked on a layer including one or more of indium tin oxide (ITO), titanium (Ti), titanium nitride (TiN), and an additional layer including one or more of Al, Ag, and Cu is stacked on the layer including one or more of Al, Ag, and Cu. However, the disclosure is not limited thereto, and the first metal layer ML1 may include metal having a relatively high reflectance.

The first metal layer ML1 may have a thickness in a range of about 500 Å to about 1000 Å. The first metal layer ML1 may reduce a risk of disconnection of the connection electrode CE2.

The second metal layer ML2 may be disposed on the first metal layer ML1. At least a portion of the second metal layer ML2 may contact at least a portion of an upper surface of the first metal layer ML1. At least a portion of the second metal layer ML2 may cover at least a portion of an upper surface of the first metal layer ML1. At least a portion of the second metal layer ML2 may contact at least a portion of the connection electrode CE2. At least a portion of the second metal layer ML2 may be disposed under at least a lower portion of the connection electrode CE2. The second metal layer ML2 may overlap the first metal layer ML1, in a plan view.

The second metal layer ML2 may cover at least a portion of the upper surface of the first metal layer ML1. The second metal layer ML2 may protect the first metal layer ML1. For example, the second metal layer ML2 may be formed after the first metal layer ML1 is formed. After the second metal layer ML2 is formed, an etching process for at least a portion of the insulating layer 100 (for example, the upper layer PDL) may be performed. Here, the second metal layer ML2 may be formed over the first metal layer ML1, thus protecting the first metal layer ML1 during the etching process for the insulating layer 100.

In an embodiment (refer to FIG. 9), the second metal layer ML2 may be formed in the contact area CTA. For example, the second metal layer ML2 may not overlap the non-display area NDA other than the contact area CTA, in a plan view. The second metal layer ML2 may overlap the contact area CTA in a plan view.

The second metal layer ML2 may include conductive material. For example, the second metal layer ML2 may include at least one or more of indium tin oxide (ITO), indium zinc oxide (IZO), Al, Ag, and Cu. However, the disclosure is not limited to the aforementioned example. The second metal layer ML2 may be connected (for example, electrically connected) to the connection electrode CE2.

The second metal layer ML2 may have a thickness less than the thickness of the first metal layer ML1. For example, the second metal layer ML2 may have a thickness in a range of about 50 Å to about 200 Å.

The second passivation layer PVL2 (or the pixel circuit layer PCL) may further include the second conductive layer SL2 and the contact part CNT that are disposed in the non-display area NDA.

The second conductive layer SL2 may be formed through a same process as the first conductive layer SL1 disposed in the display area DA. For example, the second conductive layer SL2 may be deposited through the same process as the first conductive layer SL1, and accordingly, may include a same material as the first conductive layer SL1. In an embodiment, the second conductive layer SL2 may be a layer disposed in the uppermost portion of the display device DD among the electrodes constituting the CMOS circuit elements.

At least a portion of the second conductive layer SL2 may overlap the second metal layer ML2, in a plan view. At least a portion of the second conductive layer SL2 may overlap the first metal layer ML1, in a plan view.

The second conductive layer SL2 may be electrically connected to the second electrode CE. The second conductive layer SL2 may be electrically connected to the first metal layer ML1. The first metal layer ML1 may be electrically connected to the second metal layer ML2. The second metal layer ML2 may be electrically connected with the connection electrode CE2. Therefore, the connection electrode CE2 may be electrically connected to the second electrode CE. Therefore, the second conductive layer SL2 may electrically connect the second power line PL2 (refer to FIG. 11) and the second electrode CE. Description pertaining thereto will be provided below with reference to FIG. 11.

The contact part CNT may include a first contact part CNT1 and a second contact part CNT2. In an embodiment, contact parts CNT may be provided. For example, six contact parts CNT may be formed. The number of contact parts CNT is not limited to the aforementioned example, and the number of contact parts CNT may be changed depending on the embodiment.

The contact part CNT may pass through at least a portion of the second passivation layer PVL2 (or the pixel circuit layer PCL) and connect the first metal layer ML1 and the pixel circuit layer PCL (for example, the second conductive layer SL2).

The contact part CNT may include conductive material. The contact part CNT may be filled with conductive material. For example, the contact part CNT may include tungsten (W). The contact part CNT may include conductive material, and may electrically connect the first metal layer ML1 and the second conductive layer SL2. The second electrode CE may be electrically connected to the second conductive layer SL2 through the connection electrode CE2, the second metal layer ML2, and the first metal layer ML1.

Since the second electrode CE is connected to the second conductive layer SL2 through the connection electrode CE2, the second metal layer ML2, and the first metal layer ML1, the display device DD in accordance with the disclosure may prevent a risk of disconnection of the connection electrode CE2. For example, in the case where the connection electrode CE2 is disconnected in the contact area CTA, it may be disconnected from the second electrode CE, whereby power may not be properly supplied to the pixels PXL. In accordance with the display device DD according to the disclosure, as the second metal layer ML2 is formed in the contact area CTA, even if the connection electrode CE2 is disconnected in the contact area CTA, the second metal layer ML2 may electrically connect portions of the connection electrode CE2. Accordingly, the first metal layer ML1, the second metal layer ML2, the connection electrode CE2, and the second electrode CE may be electrically connected, whereby the second electrode CE may properly supply power to the pixels PXL.

The insulating layer 100 may be disposed in the display area DA and the non-display area NDA. Hereinafter, the lower layer IL and the upper layer PDL that are disposed in the display area DA is defined as a first insulating layer, and the lower layer IL and the upper layer PDL that are disposed in the non-display area NDA is defined as a second insulating layer.

At least a portion of the second insulating layer may be connected to at least a portion of the first insulating layer. For example, at least a portion of the second insulating layer may be connected to at least a portion of the first insulating layer, so that at least a portion of the insulating layer 100 may be formed over the display area DA and the non-display area NDA. For example, the first lower layer IL1 may be formed over the display area DA and the non-display area NDA. The first lower layer IL1 may extend from the display area DA to the non-display area NDA.

At least a portion of the second insulating layer may contact at least a portion of the first metal layer ML1. At least a portion of the second insulating layer may contact a side surface of the first metal layer ML1. At least a portion of the second insulating layer may overlap at least a portion of the first metal layer ML1, in a plan view. At least a portion of the second insulating layer may expose the upper surface of the first metal layer ML1. At least a portion of the second insulating layer may contact at least a portion of the second metal layer ML2. At least a portion of the second insulating layer may be disposed between the first metal layer ML1 and the second metal layer ML2. At least one end or an end of the second insulating layer may be covered with the second metal layer ML2. At least a portion of the second insulating layer that contacts at least portions of the first metal layer ML1 and the second metal layer ML2 may be the first lower layer IL1.

For example, the first lower layer IL1 may contact at least a portion of the first metal layer ML1. The first lower layer IL1 may contact a side surface of the first metal layer ML1. The first lower layer IL1 may cover the side surface of the first metal layer ML1. The first lower layer IL1 may contact at least a portion of the upper surface of the first metal layer ML1. The first lower layer ILI may cover at least a portion of the upper surface of the first metal layer ML1. At least a portion of the first lower layer IL1 may overlap at least a portion of the first metal layer ML1, in a plan view. An end (or edge) of the first lower layer IL1 may contact the first metal layer ML1. The first lower layer IL1 may contact at least a portion of the second metal layer ML2. The first lower layer IL1 may be disposed between the first metal layer ML1 and the second metal layer ML2. An end of the first lower layer IL1 may be covered with the second metal layer ML2.

At least a portion of the second insulating layer may contact the pixel circuit layer PCL (or the second passivation layer PVL2). For example, the first lower layer IL1 may contact the pixel circuit layer PCL (or the second passivation layer PVL2). The first lower layer IL1 may contact the pixel circuit layer PCL (or the second passivation layer PVL2) in the non-display area NDA. In the display device DD in accordance with the disclosure, in an electrode deposition area S, at least a portion of the second insulating layer may be disposed on the pixel circuit layer PCL (or the second passivation layer PVL2), thus reducing a risk of disconnection of the second electrode CE.

The first lower layer IL1 may contact the pixel circuit layer PCL (or the second passivation layer PVL2) in the electrode deposition area S. At least a portion of the second insulating layer may be disposed under at least a portion of the connection electrode CE2. For example, in the electrode deposition area S, the first lower layer IL1 may be disposed under the connection electrode CE2. At least a portion of the first lower layer IL1 may contact at least a portion of the connection electrode CE2.

Experimentally, in the case where the second insulating layer is not disposed in the electrode deposition area S, the connection electrode CE2 may be directly deposited on the pixel circuit layer PCL in the electrode deposition area S. Due to a step difference in the surface of the pixel circuit layer PCL, the connection electrode CE2 may not be appropriately deposited, and the connection electrode CE2 may be disconnected in the electrode deposition area S. On the other hand, in the display device DD according to the disclosure, since at least a portion of the second insulating layer is disposed on the pixel circuit layer PCL in the electrode deposition area S, the step difference in the surface of the pixel circuit layer PCL may be mitigated, so that the risk of disconnection of the connection electrode CE2 may be reduced.

The first lower layer IL1, the second lower layer IL2, the first upper layer PDL1, the second upper layer PDL2, and the third upper layer PDL3 may have ends that are not aligned with each other. For example, the insulating layer 100 may have a stepped-shaped end. However, the disclosure is not limited to the aforementioned example, and at least some of the first lower layer IL1, the second lower layer IL2, the first upper layer PDL1, the second upper layer PDL2, and the third upper layer PDL3 may have ends aligned with each other.

Although in FIG. 9 there has been illustrated an embodiment where the first lower layer IL1 extends from the display area DA to the non-display area NDA, the disclosure is not limited thereto.

For example, at least one of the second lower layer IL2, the first upper layer PDL1, the second upper layer PDL2, and the third upper layer PDL3 may extend from the display area DA to the non-display area NDA.

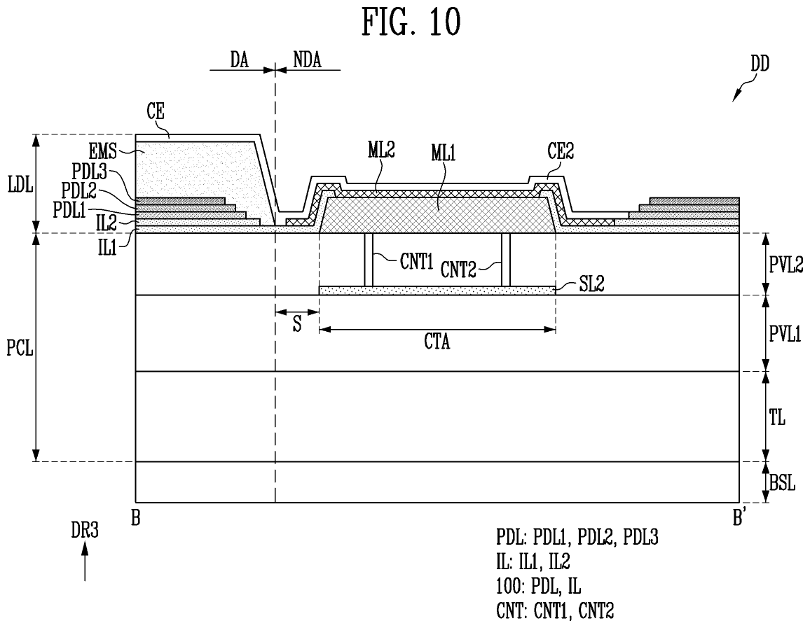

Hereinafter, a display device DD in accordance with an embodiment will be described with reference to FIG. 10. FIG. 10 is a schematic sectional view of the display device taken along line B-B′ of FIG. 1 in accordance with an embodiment. In FIG. 10, for the sake of clear and concise explanation, there are illustrated only the base layer BSL, the pixel circuit layer PCL, and the light-emitting-element layer LDL.

The embodiment of FIG. 10 differs from the embodiment of FIG. 9 in a range in which the second metal layer ML2 is disposed. Hereinafter, descriptions of contents overlapping the above-described contents may be omitted.

The second metal layer ML2 may be disposed to extend more than the contact area CTA. For example, at least a portion of the second metal layer ML2 may extend from the contact area CTA to the non-display area NDA other than (or except) the contact area CTA.

At least a portion of the second metal layer ML2 may overlap the contact area CTA in a plan view. At least a portion of the second metal layer ML2 may not overlap the contact area CTA in a plan view. At least a portion of the second metal layer ML2 may not overlap the first metal layer ML1, in a plan view. At least a portion of the second metal layer ML2 may not overlap the second conductive layer SL2, in a plan view. At least a portion of the second metal layer ML2 may be disposed on the first metal layer ML1.

In the display device DD according to the embodiment of FIG. 10, as the second metal layer ML2 is formed in the contact area CTA, even if the connection electrode CE2 is disconnected in the contact area CTA, portions of the connection electrode CE2 may also be electrically connected. Accordingly, the first metal layer ML1, the second metal layer ML2, the connection electrode CE2, and the second electrode CE may be electrically connected, whereby the second electrode CE may properly supply power to the pixels PXL.

Hereinafter, an electrical connection relationship between circuit elements will be described with reference to FIG. 11. FIG. 11 is a schematic block diagram illustrating an electrical connection structure of the light emitting element LD in accordance with an embodiment.

Referring to FIG. 11, a sub-pixel SPX may include a pixel circuit PXC configured to drive the light emitting element LD.

The pixel circuit PXC may include one or more circuit elements. For instance, the pixel circuit PXC may include transistors, and a storage capacitor. For instance, the pixel circuit PXC may include a driving transistor, a switching transistor, and a storage capacitor. However, the disclosure is not limited to the foregoing example.

The pixel circuit PXC may be electrically connected to a scan line SL and a data line DL. The scan line SL may supply a scan signal to the pixel circuit PXC and, in an embodiment, may be electrically connected to a gate electrode of the switching transistor of the pixel circuit PXC. The light emitting element LD may be configured to emit light corresponding to a data signal provided from the data line DL.

The pixel circuit PXC may be electrically connected to a first power line PL1 and a second power line PL2. For example, the first electrode AE of the light emitting element LD may be electrically connected to the pixel circuit PXC and the first power line PL1. The second electrode CE of the light emitting element LD may be electrically connected to the second power line PL2. The first power line PL1 and the second power line PL2 may be disposed on the base layer BSL.

The Power of the first power line PL1 and power of the second power line PL2 may have different potentials. For example, the power of the first power line PL1 may correspond to high-potential pixel power, which is supplied with power from a first voltage potential VDD. The power of the second power line PL2 may correspond to low-potential pixel power, which is supplied with power from a second voltage potential VSS. A difference in potential between the power of the first power line PL1 and the power of the second power line PL2 may be set to a value equal to or greater than the threshold voltage of the light emitting elements LD.

The first power line PL1 may be electrically connected to the pixel circuit PXC (for example, the driving transistor). The second power line PL2 may be electrically connected to the cathode electrode (for example, the second electrode CE) of the light emitting element LD.

In an embodiment, the second power line PL2 may be electrically connected to the second electrode CE. For example, the second electrode CE may be supplied with power through the second power line PL2 disposed in the non-display area NDA. In an embodiment, the second electrode CE disposed in the display area DA may be adjacent to the connection electrode CE2 disposed in the non-display area NDA. In an embodiment, the second electrode CE disposed in the display area DA may be electrically connected to the connection electrode CE2 disposed in the non-display area NDA. The connection electrode CE2 in the non-display area DA may be electrically connected to the second conductive layer SL2 through the first metal layer ML1 and the second metal layer ML2. In an embodiment, the second conductive layer SL2 described above may be adjacent to the second power line PL2. The second conductive layer SL2 may be electrically connected to the second power line PL2. Accordingly, the second power line PL2 may apply power to the connection electrode CE2 through the second conductive layer SL2.

In other words, the second electrode CE formed in the display area DA may be electrically connected to the second power line PL2 in the non-display area NDA. As described above, since the second electrode CE in the display area DA and the second power line PL2 may be electrically connected to each other, the power provided from the second power line PL2 may be applied to the entirety of the display area DA.

Each light emitting element LD may be connected in a forward direction between the first power line PL1 and the second power line PL2, thus forming a valid light source. The valid light sources may be grouped to form the light emitting elements LD of the sub-pixel SPX.

The light emitting elements LD may emit light at a luminance corresponding to driving current supplied thereto through the pixel circuit PXC. During each frame period, the pixel circuit PXC may supply driving current corresponding to a data signal to the light emitting element LD. The light emitting element LD may emit light at a luminance corresponding to a flowing driving current.

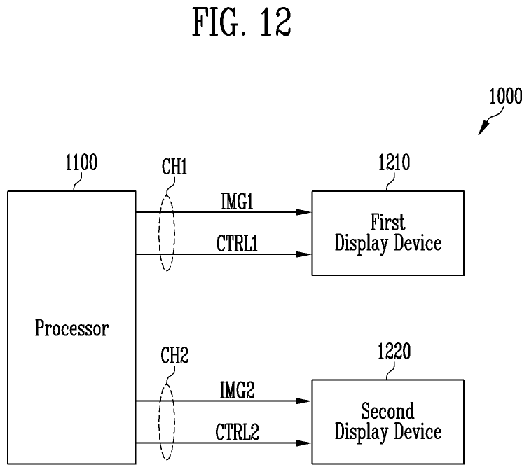

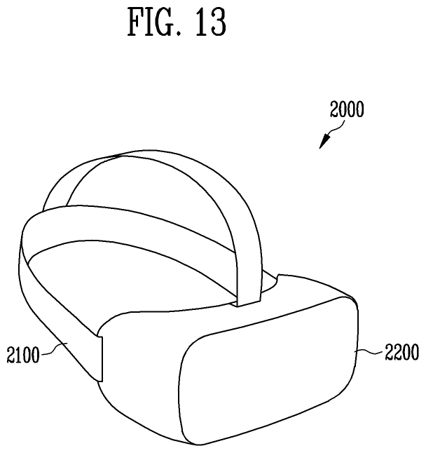

Hereinafter, a display system 1000 to which the display device DD can be applied will be described with reference to FIGS. 12 and 13.

FIG. 12 is a schematic block diagram of the display system 1000 in accordance with an embodiment. FIG. 13 is a schematic perspective diagram illustrating an application example of the display system 1000 of FIG. 12.

Referring to FIG. 12, the display system 1000 may include a processor 1100, and one or more display devices 1210 and 1220.

The processor 1100 may perform various tasks and operations. In embodiments, the processor 1100 may include an application processor, a graphic processor, a microprocessor, a central processing unit (CPU), and so on. The processor 1100 may be connected to the other components of the display system 1000 through a bus system to control the components.

In FIG. 12, there is illustrated the case where the display system 1000 may include the first and second display devices 1210 and 1220. The processor 1100 may be connected to the first display device 1210 through a first channel CH1, and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured in the same manner as the display device DD described with reference to FIG. 1. The first image data IMG1 and the first control signal CTRL1 may be provided as the input image data and the control signal to the display device of FIG. 1, respectively.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured in the same manner as the display device DD described with reference to FIG. 1.

The display system 1000 may include computing systems that provide an image display function, such as a portable computer, a mobile phone, a smart phone, a tablet personal computer (tablet PC), a smart watch, a watch phone, a portable multimedia player, a navigation system, and an ultra mobile personal computer (UMPC). Furthermore, the display system 1000 may include at least one of a head-mounted display (HMD), a virtual reality (VR) device, a mixed reality (MR) device, and an augmented reality (AR) device.

Referring to FIG. 13, the display system 1000 of FIG. 12 may be applied to a head-mounted display device 2000. The head mounted display device 2000 may be a wearable electronic device, which can be worn on the head of the user.

The head mounted display device 2000 may include a head mounted band 2100 and a display device reception casing 2200. The head-mounted band 2100 may be connected to the display device reception casing 2200. The head-mounted band 2100 may include a horizontal band and/or a vertical band to fasten the head-mounted display 2000 to the head of the user. The horizontal band may enclose the sides of the head of the user, and the vertical band may enclose the top of the head of the user. However, embodiments are not limited to the aforementioned example. For example, the head-mounted band 2100 may be implemented in the form of eyeglass frames, a helmet, and so on.

The display device reception casing 2200 may receive the first and second display devices 1210 and 1220 of FIG. 12. The display device reception casing 2200 may further receive the processor 1100 of FIG. 12.

Embodiments of the disclosure may provide a display device capable of reducing a risk of damage to electrodes of the display device, and appropriately supplying power to a pixel.

While various embodiments have been described above, those skilled in the art will appreciate that various modifications, additions and substitutions are possible, without departing from the scope and spirit of the disclosure.

Therefore, the embodiments disclosed in this specification are only for illustrative purposes rather than limiting the technical spirit of the disclosure. The scope of the disclosure must also be defined by the accompanying claims.

What is claimed is:

1. A display device, comprising:
a display area including a pixel, and a non-display area;
a pixel circuit layer including a pixel circuit;
a first electrode disposed on the pixel circuit layer;
an emission structure disposed on the first electrode;
a second electrode disposed on the emission structure in the display area;
a connection electrode electrically connected to the second electrode in the non-display area;
a first metal layer disposed on the pixel circuit layer in the non-display area; and
a second metal layer including at least a portion disposed on the first metal layer,
wherein the second metal layer electrically contacts the connection electrode.

2. The display device according to claim 1, wherein the second metal layer electrically contacts at least a portion of an upper surface of the first metal layer.

3. The display device according to claim 1, wherein at least a portion of the connection electrode is disposed on the second metal layer.

4. The display device according to claim 1, wherein
the first metal layer includes at least one or more of Al, Ag, and Cu, and
the second metal layer includes at least one or more of indium tin oxide (ITO), indium zinc oxide (IZO), Al, Ag, and Cu.

5. The display device according to claim 1, wherein
the first metal layer has a thickness in a range of about 500 Å to about 1000 Å, and
the second metal layer has a thickness in a range of about 50 Å to about 200 Å.

6. The display device according to claim 1, wherein the first metal layer and the first electrode are formed through a same process.

7. The display device according to claim 1, further comprising:
an insulating layer including at least a portion exposing the first electrode, wherein
the insulating layer comprises:
a first insulating layer disposed in the display area; and
a second insulating layer disposed in the non-display area, and
at least a portion of the insulating layer extends from the display area to the non-display area.

8. The display device according to claim 7, wherein
the insulating layer includes a lower layer and an upper layer disposed on the lower layer,
the lower layer comprises:
a first lower layer; and
a second lower layer disposed on the first lower layer, and
the upper layer comprises:
a first upper layer;
a second upper layer disposed on the first upper layer; and
a third upper layer disposed on the second upper layer.

9. The display device according to claim 8, wherein
each of the first lower layer, the second lower layer, the first upper layer, the second upper layer, and the third upper layer includes one or more of silicon oxide (SiOₓ) and silicon nitride (SiNₓ), and
each of the first lower layer, the second lower layer, the first upper layer, the second upper layer, and the third upper layer has a thickness in a range of about 100 Å to about 600 Å.

10. The display device according to claim 7, wherein
at least a portion of the second insulating layer covers a side surface of the first metal layer, and
the second metal layer covers an end of at least the portion of the second insulating layer.

11. The display device according to claim 7, wherein at least a portion of the second insulating layer is disposed between the first metal layer and the second metal layer.

12. The display device according to claim 1, wherein
the pixel circuit layer comprises:
a contact part passing through at least a portion of the pixel circuit layer;
a first conductive layer disposed in the display area; and
a second conductive layer disposed in the non-display area,
the first metal layer is electrically connected to the second conductive layer through the contact part, and
the second metal layer is electrically connected to the first metal layer.

13. A display device comprising:
a display area including a pixel, and a non-display area;
a base layer;
a pixel circuit layer disposed on the base layer, the pixel circuit layer including a pixel circuit;
a first power line and a second power line electrically connected to the pixel circuit;
a first electrode disposed on the pixel circuit layer;
an emission structure disposed on the first electrode; and
a second electrode disposed on the emission structure in the display area;
a first metal layer disposed on the pixel circuit layer in the non-display area;
a connection electrode electrically connected to the second electrode in the non-display area; and
a second metal layer including at least a portion disposed on the first metal layer, wherein
the non-display area includes a contact area,
the second power line and the connection electrode are electrically connected in the contact area, and
the second metal layer electrically contacts the connection electrode.

14. The display device according to claim 13, wherein
the second metal layer electrically contacts at least a portion of the first metal layer,
wherein the contact area includes:
a first contact area disposed on a first side of the display area;
a second contact area disposed on a second side of the display area;
a third contact area disposed on a third side of the display area; and
a fourth contact area disposed on a fourth side of the display area.

15. The display device according to claim 14, wherein
the first metal layer includes at least one or more of Al, Ag, and Cu,
the first metal layer has a thickness in a range of about 500 Å to about 1000 Å,
the second metal layer includes at least one or more of indium tin oxide (ITO), indium zinc oxide (IZO), Al, Ag, and Cu,
the second metal layer has a thickness in a range of about 50 Å to about 200 Å, and
the contact area includes:
a fifth contact area disposed between the first contact area and the second contact area; and
a sixth contact area disposed between the third contact area and the fourth contact area.

16. The display device according to claim 13, wherein
at least the portion of the second metal layer overlaps the first metal layer in a plan view, and
the contact area encloses at least a portion of the display area.

17. The display device according to claim 13, wherein at least the portion of the second metal layer overlaps the contact area in a plan view.

18. The display device according to claim 13, wherein at least a portion of the second metal layer extends from the contact area to the non-display area except the contact area.

19. The display device according to claim 13, wherein
the non-display area encloses at least a portion of the display area,
the pixel circuit layer comprises:
a contact part passing through at least a portion of the pixel circuit layer;
a first conductive layer disposed in the display area; and
a second conductive layer disposed in the non-display area,
the first metal layer is electrically connected to the second conductive layer through the contact part, and
the second metal layer is electrically connected to the first metal layer.

20. A display device, comprising:
a display area including a pixel, and a non-display area;
a pixel circuit layer including a pixel circuit;
a first electrode disposed on the pixel circuit layer;
an emission structure disposed on the first electrode;
a second electrode disposed on the emission structure in the display area;
a connection electrode electrically connected to the second electrode in the non-display area;
a first metal layer disposed on the pixel circuit layer in the non-display area; and
a second metal layer including at least a portion disposed on the first metal layer,
wherein at least the portion of the second metal layer overlaps the first metal layer and the connection electrode, in a plan view.
